(19) United States
(12) Patent Application Publication
(10) Pub. No.: US 2011/0076217 A1
(43) Pub. Date: Mar. 31, 2011

(54) PROCESS FOR GROWING RARE EARTH ALUMINUM OR GALLIUM GARNET CRYSTALS FROM A FLUORIDE-CONTAINING MELT AND OPTICAL ELEMENTS AND SCINTILLATION MADE THEREFROM

(76) Inventors: Lutz Parthier, Kleinmachnow (DE); Tilo Aichele, Jena (DE); Gunther Wehrhan, Jena (DE); Christoph Seitz, Jena (DE); Johann-Christoph Von Saldern, Jena (DE)

(21) Appl. No.: 12/889,506

(22) Filed: Sep. 24, 2010

(30) Foreign Application Priority Data
Sep. 25, 2009 (DE) 10 2009 043 003.2

(51) Int. Cl. C30B 15/00; C30B 11/00; C01F 17/00

(52) U.S. Cl. 423/263; 117/13; 117/83; 117/81

(57) ABSTRACT

The process for growing a rare earth aluminum or gallium garnet crystal from a melt includes melting an aluminum or gallium garnet of at least one rare earth, preferably Lu or Y, or a mixture of oxides of formula Me₂O₃, wherein Me represents the rare earth or aluminum or gallium. The melt also includes a fluoride anion acting as a counter ion for the rare earth and the aluminum or gallium. The components comprising the rare earth and aluminum or gallium are introduced in the melt so that the amounts of the rare earth and aluminum or gallium are defined by the formula: SE₍₃₋ₓ₎X_{(5-y)}O_{(12-2x-2y)}F_{(x+y)}, wherein 0≦x≦0.2 and 0≦y≦0.2 and 0<x+y≦0.4, and X is aluminum or gallium. The resulting crystals are used for optical elements at 193 nm, such as lenses, and as scintillation materials.

### CROSS-REFERENCE

The invention described and claimed herein below is also described in German Patent Application 10 2009 043 003.2, filed Sep. 25, 2009 in Germany. The aforesaid German Patent Application, whose subject matter is incorporated herein by reference thereto, provides the basis for a claim of priority of invention for the invention claimed herein below under 35 U.S.C. 119 (a)-(d).

### BACKGROUND OF THE INVENTION

1. The Field of the Invention

The present invention relates to processes for production of rare earth aluminum or gallium garnet crystals (SEAG, SEGG) from a fluoride-containing melt and their use for making optical elements for microlithography and scintillator applications. The invention also relates to the crystals produced by the process, and to optical elements made from them, especially lenses.

2. The Description of the Related Art

In order to reduce the structure widths in optical lithography, a high numerical aperture can be used according to the state of the art. In addition a combination of an immersion liquid with a lens having a high refractive index is also used. Aluminum garnets (AG) of yttrium (YAG) or of lutetium (LuAG) or generally of rare earths (SEAG) are used as lens material. In the scope of the present invention yttrium, scandium and lanthanum are rare earths. With these elements the UV transmission cutoff is only slightly below 193 nm. Because of that, even small amounts of crystal defects and impurities lead to a high absorption at 193 nm. The wavelength of 193 nm is employed in microlithography and the absorptions, which occur because of crystal defects in aluminum garnets of rare earths, strongly impair lens quality.

SEAG crystals, especially LuAG and YAG, are grown from the melt preferably according to the Czochralski, VGF, or Bridgman method. Because of its high melting point of about 2050° C. a large number of point defects are continuously produced in LuAG on account of thermodynamic potential. These defects are especially produced in LuAG Lu-antisites, in which Lu replaces Al and occupies empty oxygen sites in the garnet crystal lattice.

Moreover a fluxing agent or solvating agent, which is usually at least partially built into the crystal structure, is added to decrease the melting point. These point defects in the crystal structure lead to an absorption and also to an increase in the lattice parameters, which causes a reduction of the band gap. As a result the absorption due to impurities and crystal defects is further increased.

Lead oxide, lead fluoride or even boric oxide is used as a fluxing agent or solvating agent according to the prior art. All these substances are unsuitable for lithographic applications, since especially lead tends to increase absorption and fluorescence. When these fluxing agents or solvating agents are used unacceptably high absorption values continually occur at 193 nm. Even in scintillator applications fluxing agents or solvating agents interfere with the conversion of energy-rich radiation into scintillation emission in the scintillator material.

US 2007/0187645 describes a lutetium-aluminum garnet, in which fluorine atoms are introduced together with Ca or Mg alkaline earth metal, in order to protect the scintillator from radiation damage.

U.S. Pat. No. 6,630,077 B2 concerns a scintillator of formula (Tb_{0.97}Ce_{0.03})₃Al_{4.9}O₁₂ drawn from a melt, in which 1 wt. % of AIF₃ is added. U.S. Pat. No. 6,630,077 B2 generally describes the making of garnets of formula (Tb_{1-y}Ce_{y})ₐAl_{4.9}O₁₂ with 2.8≦a≦3 and 0.0005≦y≦0.2 from oxides with reduction of rare earth oxides with an oxidation number greater than 3. Less than 20 wt. % of a rare earth fluoride could be added so that a fluoride could be built in without more.

Scintillator compounds containing terbium or lutetium, which have an increased resistance to radiation damage, are known from DE 10 2004 051 519 A1. They have the formula (G_{1-x-y}AₓSE_{y})ₐD_{z}O₁₂, wherein D represents Al, Ga and/or In, G represents Tb, Y, La, Gd and/or Yb, A represents Lu, Y, La, Gd and/or Yb and SE is selected from the group consisting of Ho, Er, Tm and/or Ce, x is a number in a range from 0 to 0.2774 inclusively, y is in a range from about 0.001 to about 0.012 inclusively, a is in a range of 2.884 to about 3.032 inclusively, and z is in a range of about 4.968 to about 5.116 inclusively.

In addition, sintered and tempered scintillator compositions A₃B₂C₃O₁₂ are known from US 2007/0187645 A1.

Finally EPI 816 241 A1 describes a scintillator single crystal of the garnet type, containing praseodymium or cerium as activator.

### SUMMARY OF THE INVENTION

It is an object of the invention to provide a material, which has improved properties regarding index of refraction and transmission in comparison to those of the prior art, especially at a wavelength of 193 nm.

It is a further object of the invention to provide optical elements, such as lenses, for use in microlithography and scintillator applications, especially at a wavelength of 193 nm, made with the aforesaid material with improved index of refraction and transmission properties.

Generally the process according to the invention concerns growing a rare earth aluminum garnet crystal or a rare earth gallium garnet crystal or a mixture thereof, and especially a single crystal of the aforesaid materials, from a melt of rare earth aluminum garnet, rare earth gallium garnet, and/or a mixture of oxides of the formula X₂O₃, wherein X represents aluminum or gallium and also at least one oxide or salt of a rare earth element or elements, and, wherein the melt contains at least one fluoride as counter ion for aluminum, gallium and/or the at least one rare earth element.

The crystals grown from the aforesaid melt are also part of the subject matter of this invention.

According to the invention the “rare earth elements” and “SE” include La, Ce, Pr, Nd, Pm, Sm, Eu, Gd, Tb, Dy, Ho, Er, Tm, Yb, Lu and also Y and Sc. Preferred rare earth elements are cerium, lutetium, scandium, ytterbium, praseodymium, and europium. Lutetium is particularly preferred for lithographic applications.

Surprisingly according to the invention high quality crystals were obtained from one such melt, when ingredients comprising a rare earth element or elements and aluminum and/or gallium were introduced into the melt in amounts that are within a narrowly selected range defined in the following disclosures.

Furthermore the ingredients comprising the rare earth element or elements and aluminum and/or gallium are introduced into the melt in respective amounts corresponding to a stoichiometry defined by the following formula:

SE₍₃₋ₓ₎X_{(5-y)}O_{(12-2x-2y)}F_{(x+y)}

wherein 0≦x≦0.2 and 0≦y≦0.2 and 0<x+y≦0.4, preferably 0<x+y≦0.3, especially preferably 0<x+y≦0.2, and most preferably 0.05<x+y 0.2, and wherein X represents aluminum, gallium or mixtures thereof and SE represents a rare earth element. In a preferred embodiment y=0 and 0<x≦0.2 and preferably 0.05<x<0.15.

Crystals grown from a melt of the aforesaid composition have a high index of refraction and a higher transmission, especially at 193 nm.

A melt of this sort serves for growing a rare earth aluminum garnet and/or rare earth gallium garnet crystal, or rare earth aluminum- and rare earth gallium garnet mixed crystal, especially a single crystal, in a crystallization process from the melt. The crystallization is performed according to methods known to those skilled in the art. For this purpose the methods, for example, described in EP 1 816 241 A1 or U.S. Pat. No. 5,554,219 and including especially the Czochralski, VGF and Bridgman methods are suitable.

The melt is preferably handled in a crucible made from molybdenum, tungsten, or iridium, wherein iridium is especially preferred.

Without being bound to any particular theoretical mechanism of operation, probably crystal defects may be avoided by introduction of fluorine in the garnet lattice, wherein a rare earth, such as lutetium and two oxygen atoms or aluminum or gallium and two oxygen atoms can be replaced by a fluorine atom.

In further preferred embodiments the crystal quality according to the invention is additionally improved because evaporation of gases from the melt is at least hindered and/or fluorine is introduced from the gas phase. This improves the introduction of fluoride into the crystal during crystallization from the melt. The crystal quality is further improved when evaporation of gases from the melt is prevented and/or fluorine is fed into the melt from the gas phase.

In addition the melt is preferably contained e.g. in a gas-tight container, especially a pressurized container. In this container pressures up to 10 atm, typically up to 2 and/or 1 atm are used. Pressures of 200 to 300 mbar over standard pressure are preferred. The gas-tight container can have an atmosphere, which contains fluorine, hydrogen fluoride, CF₄, hydrogen, CO, CO₂, inert gas, especially argon and/or nitrogen, or mixtures of these gases. A mildly reducing atmosphere is preferred. In preferred embodiments the atmosphere contains so much fluorine, that the fluorine partial pressure of the melt is exceeded so that no fluorine can escape from the melt.

In a preferred embodiment of the process according to the invention the atmosphere contains argon, CO/CO₂, and CF₄, or F₂ and H₂. The presence of fluorine gas and hydrogen in an atmosphere in the container does not lead to problems, since the atmosphere is continuously kept above the decomposition temperature of HF by the melt.

In order to prevent a depletion of fluorine in the melt, a sufficient counter pressure can be applied with the help of an inert gas, especially argon, nitrogen or a combination of both, and an addition of hydrogen up to 20 vol % and/or less.

The above-described features can be combined, in order to prevent the depletion of fluorine from the melt.

Alternatively in the container the melt can be managed with a floating cover or a floating fluid to seal the melt and thus prevent escape of gas. For this purpose this cover can be made of the same material as the crucible.

An additional embodiment of the process according to the invention includes introducing a part or the entire amount of the fluorine of the fluxing agent via the gas phase, preferably as undiluted CF₄ or fluorine gas or mixed with an inert gas, such as argon or nitrogen. The otherwise absent portions of rare earth elements, gallium and/or aluminum for production of the fluxing agent with the fluorine from the gas phase were previously made up, especially by previous addition of the rare earth element or elements and aluminum and/or gallium or oxides thereof.

It was surprisingly found that the addition of fluorides shifted the transmission cutoff to shorter wavelengths relative to pure SEAG and thus permitted a higher transmission at 193 nm. Also the added fluoride salts lowered the melting point of the mixture of ingredients used to make the melt, whereby the energy consumption costs for growing the crystal were reduced.

Furthermore it was found that the number and/or concentration of thermodynamically dependent crystal structural defects is reduced, which similarly leads to an increased transmission.

Because of the procedure according to the invention it is possible to achieve an especially high purity of at least 4 N, i.e. of 99.99 wt. % and/or of 6 N, i.e. 99.9999%. This sort of high purity may not be achieved solely by the use of high purity reactants or starting ingredients, but especially the procedure according to the invention. The fraction of impurities present in the rare earths, such as Tb, Dy, Ho, Er, Tm, Yb, Y, usually amounts to at maximum 0.00005 and/or 0.00001.

In order to preferably use this effect during growth of the crystal, i.e. during its crystallization, the temperature of the melt may not exceed a certain value, which is more than 20° C., preferably more than 10° C., above the liquidus temperature.

Preferably a mixture of Al₂O₃, Ga₂O₃ and SE₂O₃ or SEAG and SEF₃ and/or AIF₃ and/or GaF₃ can be used as the raw material or starting material for making the melt.

According to a further embodiment according to the invention a part or the entire amount of the fluorine is introduced into the melt via the gas phase, and indeed preferably as undiluted fluorine gas or CF₄ or mixed with an inert gas, such as argon or nitrogen. The portions of SE or aluminum that would otherwise be absent from the stoichiometric mixture were previously made up, especially by addition of metallic or oxidized SE and/or aluminum, wherein SE means rare earth element as noted above. The melt can also be obtained by melting solid ingredients with the fluorides of aluminum and/or gallium and/or the rare earth or rare earths or by addition of at least a part of the fluoride from an atmosphere containing fluorine with addition of metallic or oxidized aluminum and/or gallium and/or the rare earth element or elements.

The invention similarly has the purpose to provide a material, which is suitable as a scintillation material for many different applications. The invention especially has the purpose to prepare this sort of material in a simply manner.

For this purpose in a preferred embodiment 0.01 to 5 Mol % of rare earth, especially of yttrium or scandium is replaced by an activator A. Principally all possible activators for scintillation can be used, as long as they do not disturb the garnet lattice. Preferred activators are praseodymium, cerium and/or europium. These activators can similarly be added with other elements as fluorides and/or oxides. Preferably then the melt, from which the crystal is drawn, has a composition, so that the grown crystal is of the formula:

(SE_{1-z}A′_{z})₍₃₋ₓ₎X_{(5-y)}O_{(12-2x-2y)}F_{(x+y)}

wherein SE is at least one rare earth ion,
X is Al and/or Ga;
A′ is at least one scintillation activator,
x and y take their previously described values, and
z is 10⁻⁴ to 0.05, but a z value of at most 0.03, especially at most 0.02, and most especially at most 0.01 is preferred. When the activator is a rare earth, then it is preferred that an additional rare earth element, which is not an activator is present in a molar quantity that corresponds to 1−z.

According to the invention crystals of the above-described type are further processed to make scintillation ceramics.

Scintillation elements made from the material according to the invention can also include translucent ceramics. For this purpose the material of the composition according to the invention is prepared as a polycrystalline powder with a grain size in the nanometer range. The preparation of the powder occurs for example by a solid state reaction, co-precipitation, other wet chemistry precipitation methods, or by a sol-gel process. The nanocrystalline powder is then hot or cold isostatically and/or uni- to multiaxially pressed to form a green body and subsequently sintered to form a ceramic scintillation body. The composition according to the invention is either already pressed during the powder preparation or the powder mixture of oxides and fluorides with the composition according to the invention is pressed to form the green body, so that the single phase composition is adjusted or changed by a solid state reaction during sintering. The sintering is performed by conventional high temperature sintering processes, such as for example the solid phase sintering, the fluid phase sintering especially for sintering two-phase green bodies. During these procedures the fluoride components present act as sintering assisting agents. An additional sintering method is, for example, spark-plasma sintering, in which the pressing of the powder already occurs in the sintering unit, so that a separate green body preparation step can be avoided.

The invention also concerns the use of the materials made by the process for scintillation applications for crystalline materials, especially in the form of a single crystal, with high refractive index and high transmission at 193 nm, for an optical lens in the field of optical lithography.

In a special embodiment the invention concerns the use of the material made by the process for scintillation applications. This material is used above all in nuclear medicine in positron emission tomography, especially for detectors, such as the annihilation photon detector, in order to produce three-dimensional cross sectional images of organs, for illumination or irradiation of mass-produced goods, and for exploratory reconnaissance, such as searching for oil and/or gas.

### EXAMPLE 1

99.46 g of Lu₃Al₅O₁₂ garnet powder are weighed out, introduced into an iridium crucible, and mixed with 0.54 g of AIF₃. After that the mixture was held over night at 2050° C. and 1 bar pressure in an argon atmosphere containing 2% CF₄ in a VGF oven and subsequently a crystal was grown from the mixture using the VGF method, in order to obtain a transparent crystal.

### EXAMPLE 2

140.15 g of Lu₂O₃, 60.28 g (59.85+0.34) of Al₂O₃ and 0.66 g of Pr₂O₃ are weighed out, introduced into an iridium crucible, and mixed with 0.98 g of AIF₃. After that the mixture was held over night at 2050° C. and 1 bar pressure in an argon atmosphere containing 1.5% CF₄ in a VGF oven and subsequently a crystal was grown from the mixture using the VGF method, in order to obtain a scintillation crystal.

In both cases crystal elements of 20000 ph/Mev, 17 ns, and 5662 keV were obtained.

Generally the methods for making the ceramics are known to those skilled in the art and for example described in:
H. Ogino, A. Yoshikawa, M. Nikl, A. Krasnikov, K. Kamada, and T. Fukuda, Growth and scintillation properties of Pr-doped Lu₃Al₅O₁₂ crystals, Journal of Crystal Growth, 287:335-338, 2006;
H. Ogino, A. Yoshikawa, M. Nikl, K. Kamada, and T. Fukuda, Scintillation characteristics of Pr-doped Lu₃Al₅O₁₂ single crystals, Journal of Crystal Growth, 292:239-242, 2006; and
L. Swiderski, M. Moszynski, A. Nassalski, A. Syntfeld-Kazuch, T. Szczesniak, K. Kamada, K. Tsutsumi, Y. Usuki, T. Yanagida, and A. Yoshikawa, Light Yield Non-Proportionality and Energy Resolution of Praseodymium Doped LuAG Scintillator, IEEE TRANSACTIONS ON NUCLEAR SCIENCE, 56:934-938, 2009.

While the invention has been illustrated and described as embodied in a process for growing rare earth aluminum or gallium garnet crystals from a fluoride-containing melt and optical elements and scintillator made therefrom, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed is new and is set forth in the following appended claims.

We claim:

1. A process for growing a rare earth aluminum garnet crystal, a rare earth gallium garnet crystal or a mixture thereof
from a melt of rare earth aluminum garnet, rare earth gallium garnet, and/or mixtures thereof, at least one rare earth-containing fluoride, and/or a mixture of oxides of formula Me₂O₃, wherein Me represents a rare earth element or elements, aluminum, or gallium;
wherein said melt contains fluoride anion as a counter ion for said rare earth element or elements and said aluminum and/or said gallium; and
wherein ingredients of the melt comprise said rare earth element or elements and said aluminum and/or said gallium and said ingredients are present in the melt in amounts according to the following formula:
SE₍₃₋ₓ₎X_{(5-y)}O_{(12-2x-2y)}F_{(x+y)}
wherein 0≦x≦0.2 and 0≦y≦0.2 and 0<x+y≦0.4; and
X represents said aluminum, said gallium, or mixtures thereof, and
SE represents the rare earth element or elements.

2. The process according to claim 1, wherein y=0 and 0<x≦0.2.

3. The process according to claim 1, wherein y=0 and 0.05<x<0.15.

4. The process according to claim 1, wherein the rare earth element is Lu or Y.

5. The process according to claim 4, wherein said melt is produced by melting said rare earth aluminum garnet and/or said oxides with said at least one fluoride of said rare earth element or elements and/or with at least one fluoride of said aluminum.

6. The process according to claim 5, wherein at least a part of the at least one fluoride is added to the melt from a fluorine-containing atmosphere with addition of said aluminum and/or of said rare earth element or elements and/or of said oxides of said aluminum and/or of said rare earth element or elements.

7. The process according to claim 1, wherein from 0.01 to 5 Mol % of said rare earth element or elements are replaced by a scintillation activator.

8. The process according to claim 7, wherein said scintillator activator is selected from the group consisting of praseodymium, cerium and europium.

9. The process according to claim 1, wherein said melt is contained in a gas-tight container.

10. The process according to claim 9, wherein the gas-tight container is a pressurized container.

11. The process according to claim 9, wherein the gas-tight container contains fluorine, hydrogen fluoride, carbon tetrafluoride, hydrogen, carbon monoxide, carbon dioxide and an inert gas, or mixtures thereof.

12. The process according to claim 11, wherein the inert gas is argon or nitrogen.

13. The process according to claim 1, wherein a temperature equal to 20° C. above a melting temperature of a solid mixture of said ingredients of said melt is not exceeded when the process is performed.

14. The process according to claim 1, wherein a temperature equal to 10° C. above a melting temperature of a solid mixture of said ingredients of said melt is not exceeded when the process is performed.

15. A crystal obtainable by the process according to claim 1.

16. An optical element comprising a crystal, said crystal being obtainable by the process according to claim 1.

17. A scintillation material with a purity greater than 4 N (99.99 wt. %), said scintillation material being obtainable by the process according to claim 7.

18. A lens, prism, optical window or optical component for DUV lithography, a stepper, an excimer laser, a microchip, as well as integrated circuits and electrical devices, which contain said chips, and a scintillator, which contain or are made with a crystal obtainable according to the process defined in claim 1.
